(19) United States
(12) Patent Application Publication
(10) Pub. No.: US 2026/0298566 A1
(43) Pub. Date: Oct. 1, 2026

(54) Method and Kit for Attaching a Storage Box to a Pistol Magazine, Including a Replacement Base for Substituting the Original Magazine Base

(71) Applicants: Yair Kavalerchik, Lotan (IL); Asher Serfaty, Binyamina (IL)

(72) Inventors: Yair Kavalerchik, Lotan (IL); Asher Serfaty, Binyamina (IL)

(21) Appl. No.: 19/634,188

(22) Filed: Mar. 31, 2026

(30) Foreign Application Priority Data
Apr. 1, 2025 (IL) 319990

(51) Int. Cl. F41A 9/65; F41A 35/00

(52) U.S. Cl. CPC F41A 9/65; F41A 35/00

(57) ABSTRACT

A modular kit and method for equipping a standard pistol magazine with an accessible storage solution for emergency identification gear. The kit comprises a replacement magazine base, a storage housing, and a pivotally attached access door. The replacement base is engineered with specific recesses, protrusions, and a locking aperture to mirror the internal geometry of a standard magazine, allowing it to securely replace an original base plate. The storage housing features a rail-and-interlock system that slideably engages with the replacement base, creating a secure, integrated compartment at the bottom of the magazine. This configuration allows for the discrete storage of an identification cap or “hat” directly on the firearm. By converting a standard magazine into an upgraded storage-capable unit, the system ensures that critical identification and emergency equipment remain immediately available for deployment during high-stress encounters or tactical emergencies without interfering with firearm operation.

### RELATED APPLICATIONS

This application claims the benefit of priority of Israeli Patent Application No. 319990 filed on Apr. 1, 2025, the contents of which are incorporated herein by reference in their entirety.

### TECHNICAL FIELD

The present invention relates to a method and kit for attaching a miniature storage box to a pistol magazine, featuring a replacement base designed to substitute the magazine's original base plate (also known as “floor plate”).

### BACKGROUND OF THE INVENTION

Individuals who carry firearms (Concealed carry) often also carry identification hats—typically bright-colored visor hats with standardized markings—to distinguish themselves as allies rather than threats. Undercover police detectives and forces always use this kind of hat as they do not wear police uniform. Security personal in public places always carry this kind of hat in their pocket. In the event of a shooting incident in a public space, an armed civilian engaged in defending against terrorists or criminals may be mistaken for an adversary by other armed citizens or security forces.

The identification hat plays a crucial role in preventing such misidentifications, potentially saving lives. However, armed civilians with concealed carry permits or undercover security personnel sometimes accidentally leave their identification hats at home or in their vehicles or deliberately store the hat in their bag, pouch, or in a back pants pocket of which it is hard to pull the hat from. In a sudden emergency, they may find themselves forced to engage without this critical identifier, or struggle to find and pull the hat.

The present invention addresses this issue by providing a practical solution, along with other related benefits, as the hat will always be found on the firearm and in front of the shooter's eye of sight, allowing him to keep aiming at the threat and in the same time pull the hat with their other hand.

### THE DRAWINGS

FIG. 1 depicts the parts of a magazine (100) of a pistol.

FIG. 2 depicts the kit (10) and its parts (20) (30) (40) and (50).

FIGS. 3A-3D depict the replacement base (20) of the kit (10).

FIGS. 4A-4D depict the storage box (30) of the kit.

FIGS. 5A-5D depict the hinged lid-like door (40) of the storage box.

FIGS. 6A-6D depict the belt clip (50) of the kit.

FIG. 7 is a schematic depiction of the kit 10B.

### THE INVENTION

The aim of the present invention is to disclose a kit (10) for assembling a miniature storage box (30) to the bottom (101) of an existing standard magazine (100) of a pistol. The kit (10) includes a replacement base plate (20), the storage box (30), and a hinged lid-like door (40).

The replacement base plate (20) has bottom base rails (24), configured to replace the original base plate (102) of the existing standard magazine. The replacement base includes recesses (21), protrusions (22) and a hole (23) that correspond to recesses (103), protrusions (104) and a hole (105) of the original base plate, in order to allow the replacement base to be securely mounted on the bottom of the existing standard magazine.

The storage box (30) has top box rails (31) that are configured to slide and interlock with the bottom base rails of the replacement base by sliding and fitting the top box rails with the bottom base rails.

The hinged lid-like door (40) is axially attached to the bottom of the storage box and configured to close the storage box. The hinge also has a spring that automatically closes the door when the hat is being pulled out such that the hinge won't interrupt the shooter's performance with the firearm.

The kit enables the user to assemble the storage box to the bottom of his existing standard magazine and to store inside it his identification hat for being available in case of emergency. The basic assumption is that in an emergency, the user will in any case take with him the gun and the magazines (at least one of which includes the kit that includes the box in which the identification cap is permanently stored for cases of emergency).

The present invention also refers to a method for converting the existing standard pistol magazine into an upgraded storage magazine that includes the following steps: (a) providing the kit as described above, (b) removing the original base plate from the existing standard magazine, (c) mounting the replacement base of the kit to the bottom of the existing standard magazine, and (d) attaching the storage box of the kit, including the hinged lid-like door, to the replacement base in a manner that allows for the storage of the emergency identification cap, thereby ensuring the availability of the cap in case of an emergency.

The kit (10) may further include a belt clip (50), which features clip rails (51) that correspond to the bottom base rails (24) of the replacement base (20). This design allows users to securely attach the miniature storage box (30) to their belt or pants, with the storage box being assembled to the belt clip via the matching rails.

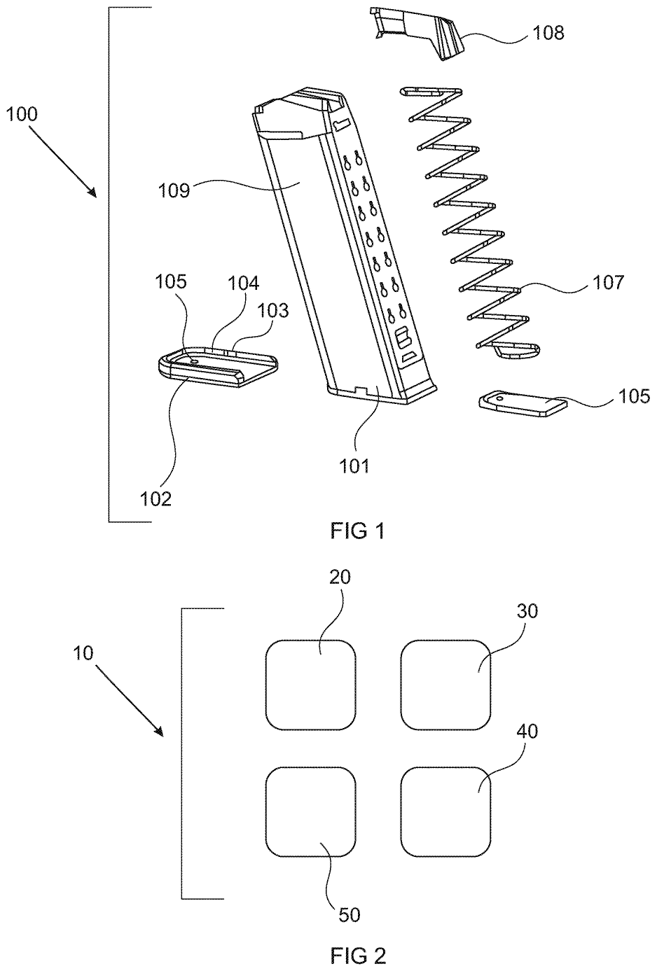

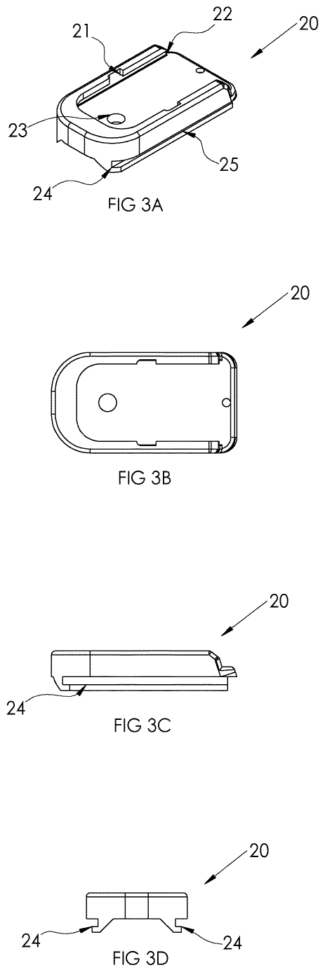

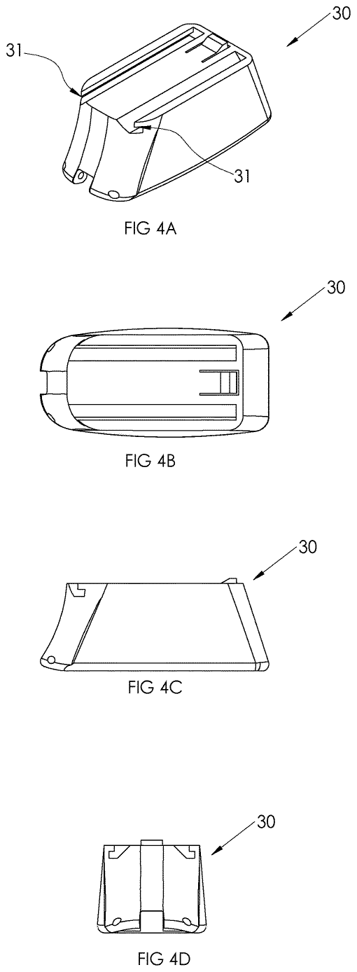

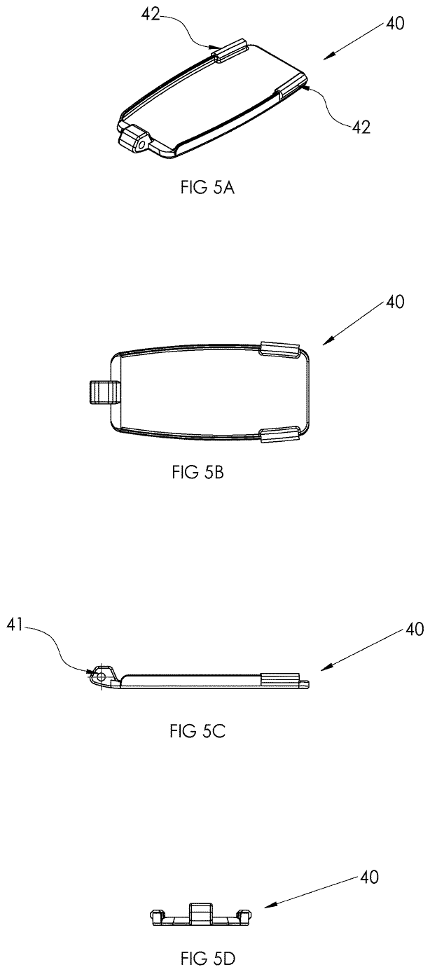

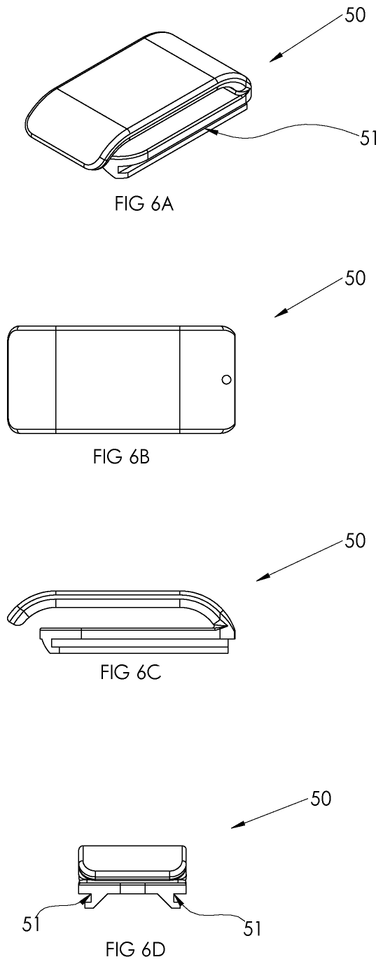

FIG. 1 depicts the parts of the existing standard pistol magazine (100) that includes the bottom (101), the original base plate (102) with its recesses (103), protrusions (104) and a hole (105), the lock plate (106), the spring (107), the follower (108), and the body (109). FIG. 2 depicts schematically the kit (10) and its parts. FIG. 3A 3D depict the replacement base (20) in several views; FIGS. 4A-4D depict the storage box (30) in several views; FIGS. 5A-5D depict the hinged lid-like door (40) in several views; and FIGS. 6A-6D depict the belt clip (50) in several views;

In addition to the aforementioned embodiments, the present invention further relates to a kit (10B) designed for the assembly of a miniature emergency button mechanism (30B) onto the base plate (101) of a standard firearm magazine (100).

The kit (10B) comprises the replacement magazine base plate (20) and the emergency button mechanism (30B). The mechanism (30B) integrates the following components: Internal Power Source (30B1): Provides dedicated energy to the system; Activation means (30B2): A versatile trigger mechanism which may include a spring-loaded mechanical button, a capacitive touch sensor, an electronic switch, or similar activation components; Electronic Control Unit (ECU) (30B3): A circuit board configured to process the activation signal; and Transmitter and Antenna (30B4): Facilitates the broadcast of a signal generated by the ECU upon activation.

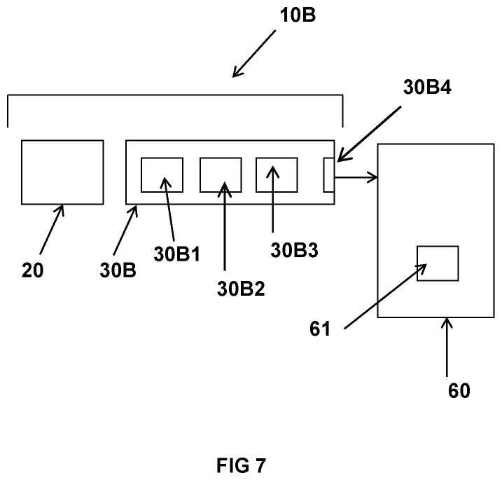

The transmitted signal is received by a mobile application (61) on the user's smartphone (60). This application is pre-configured to automatically relay a distress signal to a centralized control unit (e.g., a law enforcement dispatch or emergency monitoring center). FIG. 7 is a schematic depiction of the kit 10B and the mobile device (smartphone) (60).

The distress signal transmitted from the mobile device includes critical data, specifically the user's real-time geographical coordinates and identification information. By integrating the activation button directly onto the firearm magazine, the system ensures that the user can initiate an emergency alert even when they are unable to access their mobile phone or other traditional communication devices. Consequently, the complete system encompasses the kit (10B) in communication with the user's mobile device, which acts as a bridge to transmit the final distress signal to the designated control unit.

In addition to the above, the present invention also refers to a modular magazine-mounted system for autonomous ammunition management and low-cost emergency Signaling. The present invention relates also to a non-invasive, modular electronic enhancement for firearms. It addresses the critical “Safety Gap”—the inability to alert emergency services during an active engagement—and the “Maintenance Gap”—the lack of objective data regarding a firearm's operational readiness. Traditional “Smart Guns” are cost-prohibitive, often exceeding 1,500 USD, and require permanent, invasive modifications. The present invention solves these problems by providing an economical, high-utility retrofit via a modular Smart Box (approx. 50 mm×30 mm×20 mm) that attaches exclusively to a proprietary rail-equipped magazine floorplate. Economical SOS Communication Hub (Dual-Tier Architecture): The core of this aspect of the present invention is a low-cost, recessed, rear-facing SOS button positioned for intuitive activation. By utilizing existing mobile infrastructure or streamlined IoT modules, the system delivers professional-grade safety at a lower cost compared to integrated smart-weapon systems:

Tethered BLE Tier (Value Model): Utilizes Bluetooth Low Energy (BLE) to handshake with a mobile device. This version leverages the smartphone's existing GPS and cellular link to contact 911, significantly reducing hardware costs. It features a rechargeable battery and USB-C port for long-term sustainability.

Autonomous eSIM Tier (Pro Model): Incorporates an integrated eSIM and GNSS (GPS) module, allowing the Smart Box to function as a standalone, low-cost IoT node capable of transmitting location data independently of a smartphone.

Low-Cost Inertial Sensing and Ammunition Management: The system utilizes a standard, high-G 3-axis accelerometer to monitor the firearm's mechanical cycle. This cost-effective sensor detects the unique vibration signatures of a discharge followed by a slide-reset, processing and doing Edge-Computing by an internal microprocessor (“Brain”), a Nordic nRF54L-series (or equivalent 2026-standard) System-on-a-Chip (SoC), providing: Real-Time Round Counting: Updates a simplified, rear-facing OLED screen to inform the shooter of remaining ammunition at a glance.

Predictive Maintenance & Analytics: Data is synced to a mobile application that tracks the firearm's cumulative lifecycle, providing high-level maintenance alerts and health diagnostics to prevent costly mechanical failures and ensure the weapon remains in peak functional condition. This is done by a Recoil-Signature Algorithm coded in the SoC.

Mechanical Integrity and Interface: The Smart Box is part of a proprietary kit, attaching only to a specialized rail-adapter floorplate. This modularity ensures the system is universally compatible and easily transferable, further reducing the “cost-per-firearm” for users with multiple weapons. To ensure durability, all internal electronics are encapsulated in a shock-absorbent resin, protecting the low-cost sensors and battery from recoil impulses and high-impact reloads.

Ammunition Counting and Maintenance Monitoring Mechanism. The present invention addresses the critical need for real-time situational awareness regarding ammunition levels, particularly in high-stress operational environments where a user may fail to manually track discharged rounds. The system comprises a modular electronic enhancement integrated into a replacement magazine base plate, featuring an accelerometer calibrated to detect firearm-specific recoil (distinct from standard handling or movement), a microprocessor for data analysis, and a user interface (UI) for visual feedback, such as an LED indicator or a micro-display.

System Components: The system includes, but is not limited to, the following integrated components:

System-on-Chip (SoC): A BLE (Bluetooth Low Energy) chip serving as both a radio transceiver and a central processing unit (e.g., Nordic nRF54L), configured to process accelerometric data and manage system logic.

Tri-axial Accelerometer: Configured to monitor motion across three axes.

Power Source: An integrated rechargeable battery, including a USB-C charging port.

Micro-Display: A low-power, monochromatic screen for minimal data visualization.

Recessed Emergency Button: A side-mounted SOS button, designed to prevent accidental actuation, requiring a prolonged press (e.g., 3-4 seconds) for activation.

Rear Calibration Interface: A button positioned adjacent to the display for system configuration and BLE pairing. This interface allows the user to manually set or reset the ammunition count (e.g., incremental adjustment of magazine capacity).

Ammunition Counting Logic: The system identifies a discharge event by analyzing a high-frequency sampling window (e.g., ~0.1 seconds) to detect specific motion signatures:

Recoil Detection: Sudden shifts in the Z-axis (muzzle rise/fall) and the Y-axis (rearward slide cycling).

Cycling Detection: The forward movement of the slide as it chambers a subsequent round (Y-axis).

The microprocessor is configured to map and distinguish “Accelerometric Signatures” unique to live fire, effectively filtering out “legitimate” non-firing movements such as holstering, storage in a safe, or dry-fire practice.

Firearm Maintenance and Diagnostics (Mechanical Wear Analysis): The system further functions as a diagnostic tool by:

Usage Tracking: Monitoring total round counts per magazine and cumulative rounds fired by the firearm.

Failure Analysis: Identifying and logging mechanical malfunctions (stoppages) per magazine to provide “End-of-Life” or maintenance alerts for worn components.

Predictive Maintenance: Recording continuous wave signatures of the recoil profile. The system compares real-time data against a baseline signature; deviations in the wave pattern are utilized to diagnose issues such as degraded recoil springs, ammunition inconsistencies, or excessive fouling/lack of lubrication.

As stated above the present invention also refers to a modular, non-invasive electronic enhancement system (10B) for a firearm for sending an emergency signal. The system includes (a) the replacement magazine base (20) configured to replace an original base plate of the standard firearm magazine (100), the replacement base comprising: a mounting interface including recesses (21), protrusions (22), and an aperture (23) configured to mirror the internal locking geometry of the standard magazine; and a set of integrated external rails (24) providing a proprietary mounting platform; (b) a modular smart-housing (30B) configured to slideably engage and interlock with the integrated external rails (24) of the replacement base, the housing containing an emergency signaling mechanism comprising: an internal power source and an Electronic Control Unit (ECU); an activation interface consisting of a recessed, rear-facing SOS button positioned for intuitive thumb activation while the magazine is inserted in a firearm; and a wireless transmitter and antenna configured to broadcast a local trigger signal upon engagement of the activation interface; (c) a dual-tier communication architecture wherein the local trigger signal is received by a paired mobile computing device, said device being configured with an application to automatically relay a distress signal-including real-time geographical coordinates and user identification data-to a remote emergency control unit; wherein the system provides a low-cost, retrofit solution for autonomous emergency signaling and ammunition management without requiring permanent modification to the firearm's frame or slide.

The present invention also includes the modular, non-invasive electronic system for ammunition tracking and firearm diagnostics, configured to be integrated into a firearm magazine (100), the system comprising: a replacement magazine base (20) configured to replace an original magazine floorplate, the base providing a housing for electronic components and a mounting interface for a magazine body; a sensing and processing architecture disposed within the housing, comprising: A tri-axial accelerometer configured to sample high-frequency motion data along at least a first axis corresponding to muzzle displacement and a second axis corresponding to slide cycling; a microprocessor (SoC) configured to execute an algorithm for identifying accelerometric signatures unique to a live discharge event, wherein said algorithm distinguishes between live fire, dry fire, and non-operational handling; a memory module configured to log cumulative discharge data for the purpose of monitoring mechanical wear and maintenance intervals; user interface (UI) integrated into the base, comprising: a visual display configured to provide real-time ammunition count and system status; a first manual actuator (rear-facing) configured for system calibration, BLE pairing, and manual ammunition count adjustment; a second manual actuator (recessed side-mounted) configured to initiate an emergency SOS signal through a paired mobile device; a power management system comprising an internal rechargeable battery and a standardized charging port (USB-C); wherein the system is characterized by its ability to diagnose firearm malfunctions and maintenance requirements by comparing real-time recoil wave-patterns against a baseline signature stored in the memory module.

What is claimed is:

1. A kit (10) for assembling a miniature storage box (30) to the bottom (101) of an existing standard pistol magazine (100), the kit comprising:
(a) a replacement base (20) having bottom base rails (24), configured to replace an original base plate (102) of the existing standard magazine;
wherein the replacement base includes recesses (21), protrusions (22), and a hole (23) that correspond to recesses (103), protrusions (104), and a hole (105) of the original base plate, thereby allowing the replacement base to be securely mounted on the bottom of the existing standard magazine;
(b) storage box (30) having top box rails (31) configured to slide and interlock with the bottom rails base of the replacement base, securing the storage box to the replacement base; and
(c) a hinged lid-like door (40) axially attached to the bottom of the storage box and configured to open and close, allowing access to the storage box;
wherein the kit enables a user to attach the storage box to the bottom of an existing standard magazine and store an identification hat inside, ensuring its availability in case of an emergency.

2. A method for converting an existing standard pistol magazine into an upgraded storage magazine, comprising: (a) providing a kit as described in claim 1; (b) removing an original base plate from the existing standard magazine; (c) mounting a replacement base of the kit to a bottom of the existing standard magazine; and (d) attaching a storage box of the kit, including a hinged lid-like door, to the replacement base in a manner that allows for the storage of an emergency identification cap, thereby ensuring availability of the cap in case of an emergency.

3. A method for providing an accessible storage solution for an emergency identification cap on a firearm, the method comprising:
(a) Providing a modular assembly kit (10) comprising:
a replacement base (20) configured with a mounting interface corresponding to the structural recesses (103), protrusions (104), and locking aperture (105) of a standard pistol magazine (100);
a storage housing (30) configured to slideably engage with the replacement base (20) via a rail-and-interlock system (24, 31); and
an access door (40) pivotally coupled to the storage housing (30);
(b) modifying a standard pistol magazine (100) by:
removing the original base plate (102) from the magazine body;
securing the replacement base (20) onto the bottom (101) of the magazine in place of the original plate;
(c) integrating the storage housing (30) by:
sliding the top rails (31) of the housing into the bottom rails (24) of the replacement base until the components are interlocked;
(d) storing an identification cap within the storage housing (30) via the access door (40), such that the identification cap is maintained in an immediately available state on the firearm for deployment during an emergency.
